(19) United States
(12) Patent Application Publication
(10) Pub. No.: US 2023/0089699 A1
(43) Pub. Date: Mar. 23, 2023

(54) BLIND FEEDTHROUGH CONNECTION HAVING COAXIAL ALIGNMENT

(71) Applicant: Raytheon Company, Waltham, MA (US)

(72) Inventor: Kyle Trube, Marshfield, MA (US)

(73) Assignee: Raytheon Company, Waltham, MA (US)

(21) Appl. No.: 17/477,702

(22) Filed: Sep. 17, 2021

(51) Int. Cl. H01R 12/71; H01R 13/621

(52) U.S. Cl. CPC H01R 12/712; H01R 13/6215

(57) ABSTRACT

Methods and apparatus for an assembly including a circuit card coupled to an alignment bracket having a bracket mounting hole with an interposer board having a front and back connectors and a mounting hole. The front connector is mated with the circuit card and the back connector is configured and positioned to mate with a test connector of a unit under test (UUT). An alignment plate has a plate mounting hole. First and second alignment pins may be rotatably engaged to position the connectors in relation to the alignment plate.

### BACKGROUND

As is known in the art, blind feedthrough connections for circuit cards may be challenging. For example, a double-sided blind mate interposer circuit board may need to be mounted to a plate in a precise location. An interposer circuit board refers to a circuit board providing an electrical interface routing between one socket or connection to another. There should be precise alignment to the mounting plate coupled with precision alignment for the connection which may include mating connectors on both sides of an interposer board.

### SUMMARY

Embodiments of the disclosure provide an assembly including a mechanism for fastening and aligning an interposer board to a mounting plate with precise coaxial alignment for connector blind mates on both sides of the interposer board. In embodiments, an interposer circuit board includes tightly toleranced mounting holes that are located in reference to connector pin locations. The plate to which the interposer board is mounted features a tightly toleranced hole and slot configured to line up with the mounting holes on the interposer board. In embodiments, an alignment pin facilitates fastening and aligning an interposer board to the mounting plate. In some embodiments, the alignment pin includes male threads, a hexagonal feature, and a number of smooth surfaces for optimal alignment. A respective first alignment pin may slide through each of the mounting holes on the interposer board and through the hole and the slot on the mounting plate. A second alignment pin may include a female thread, and hexagonal feature, and a variety of smooth surfaces for optimal alignment. The female threaded pin is then fastened to the male threaded pin on the back side of the mounting plate. In embodiments, the alignment pin is tightened through the use of features, such as hexagonal surfaces, on the male and female threaded pins. With his arrangement, the interposer board and connectors are secured in a precise location. The first and second types of alignment pins, which may serve as fasteners, provide precisely located guide pins for the mating connectors to be aligned during installation.

The first and second alignment pins provide a coaxial alignment mechanism for accurate engagement of connector mate on either side of the interposer board and may allow fastening of the interposer board to the alignment plate which positions the board precisely to plate datum features.

In one aspect, an assembly comprises: a circuit card having a first connector; an alignment bracket coupled to the circuit card, the alignment bracket having a bracket mounting hole; an interposer board having a front connector and a back connector and an interposer mounting hole, wherein the front connector is mated with the first connector and the back connector is configured and positioned to mate with a test connector of a unit under test (UUT); an alignment plate having a plate mounting hole; a first alignment pin having first and second ends, wherein the first end is captured by the interposer mounting hole, the plate mounting hole and the second end is configured for insertion into a bracket of a Unit Under Test (UUT); and, a second alignment pin having first and second ends, wherein the first end is captured in the bracket mounting hole of a test circuit card and the second end is secured to the first end of the first alignment pin.

A system can further include one or more of the following features: the second end of the second alignment pin is threadably engaged to the first end of the first alignment pin, the second end of the second alignment pin is secured to the first end of the first alignment pin with a threaded male/female connection, the first and second alignment pins are concentrically positioned, the first alignment pin includes a shoulder to abut a surface of the interposer board, the interposer plate is positioned in relation to the alignment plate to position the back connector for mating with the test connector of the UUT, the back connector comprises a multigig connector, the second end of the second alignment pin is flared to abut a surface of the alignment plate, the alignment plate forms part of a backplane assembly, a test basket coupled to the alignment plate, and/or the test bracket includes slots to accept the UUT.

In another aspect, a method comprises: employing a circuit card having a first connector; employing an alignment bracket coupled to the circuit card, the alignment bracket having a bracket mounting hole; employing an interposer board having a front connector and a back connector and an interposer mounting hole, wherein the front connector is mated with the first connector and the back connector is configured and positioned to mate with a test connector of a unit under test (UUT); employing an alignment plate having a plate mounting hole; employing a first alignment pin having first and second ends, wherein the first end is captured by the interposer mounting hole, the plate mounting hole and the second end is configured for insertion into a bracket of a Unit Under Test (UUT); and employing a second alignment pin having first and second ends, wherein the first end is captured in the bracket mounting hole of a test circuit card and the second end is secured to the first end of the first alignment pin.

A method can further include one or more of the following features: the second end of the second alignment pin is threadably engaged to the first end of the first alignment pin, the second end of the second alignment pin is secured to the first end of the first alignment pin with a threaded male/female connection, the first and second alignment pins are concentrically positioned, the first alignment pin includes a shoulder to abut a surface of the interposer board, the interposer plate is positioned in relation to the alignment plate to position the back connector for mating with the test connector of the UUT, the back connector comprises a multigig connector, the second end of the second alignment pin is flared to abut a surface of the alignment plate, the alignment plate forms part of a backplane assembly, a test basket coupled to the alignment plate, and/or the test bracket includes slots to accept the UUT.

### BRIEF DESCRIPTION OF THE DRAWINGS

The foregoing features of this disclosure, as well as the disclosure itself, may be more fully understood from the following description of the drawings in which:

FIG. 1 is an isometric view of circuit cards connected to a backplane by a blind feedthrough connector;

FIG. 2A is an exploded side view of a coaxial alignment pin assembly for blind feedthrough connection with an interposer circuit board;

FIG. 2B is a front view of the backplane system of FIG. 1 populated with one circuit card;

FIG. 2C is a side view of the backplane system of FIG. 2B populated with one circuit card;

FIG. 2D is a cross-sectional side view showing detail of the coaxial alignment pin assembly of FIG. 2A; and

FIG. 3 is an exploded isometric view of a backplane assembly matable to a test basket configured to receive UUT circuit cards for connection to connectors.

### DETAILED DESCRIPTION

Embodiments of the disclosure provide a mechanism configured for a double-sided blind mate to an interposer circuit board mounted to an alignment plate for precise alignment to enable the successful mating of connectors on both sides of the interposer board. In embodiments, first and second types of alignment pins can be secured together for fastening and aligning the interposer board to the plate and providing precise coaxial alignment for connector blind mates to be made on both sides of the interposer board.

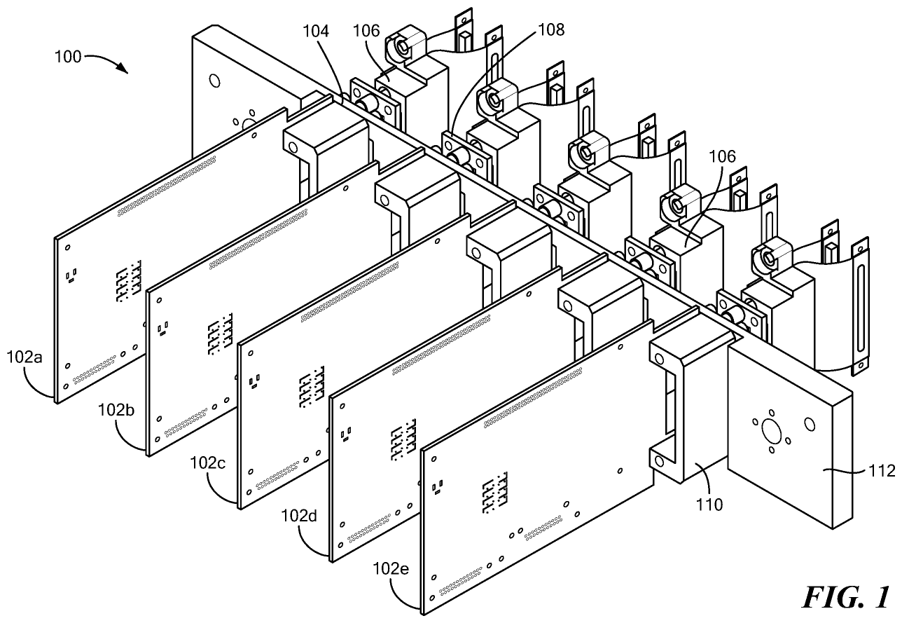

FIG. 1 shows a system 100 including a series of circuit boards 102a-e coupled to an interposer board 108 by blind feedthrough connector assemblies. Interposer board 108 is mounted with coaxial alignment pins in accordance with example embodiments of the enclosure. Respective interposer boards 108 can include connectors to connect the circuit boards 102 and the UUTs. UUTs can be sequentially attached, tested, and removed. An alignment bracket 110 can be coupled to the circuit boards 102. The various components may be positioned in relation to an alignment plate 112, as described more fully below. It is understood that any suitable connector type, such as a multigig connector, can be used.

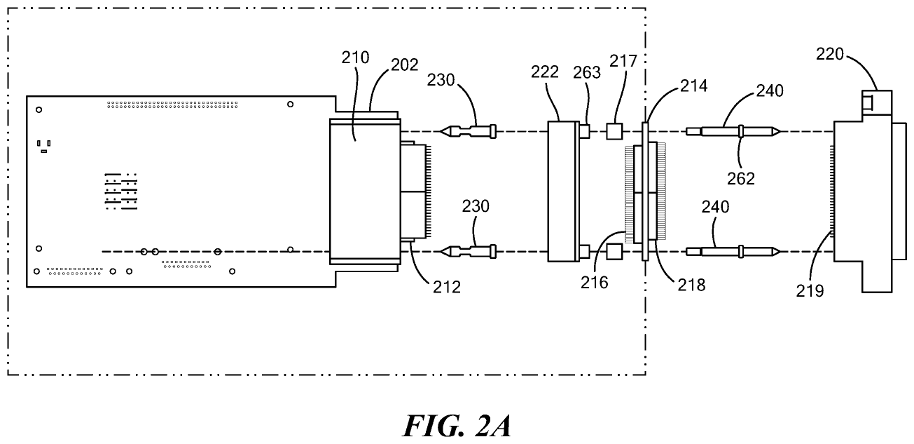

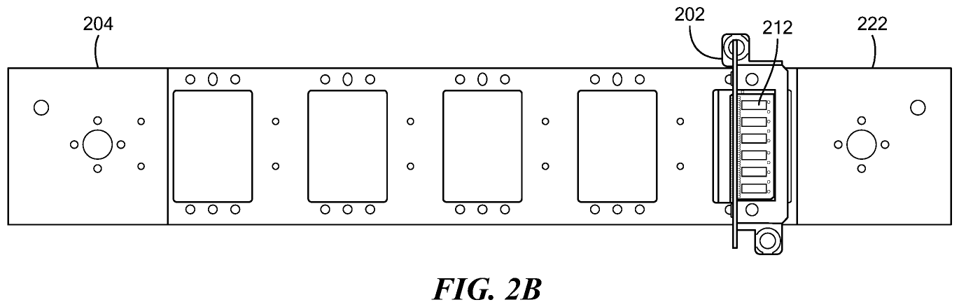

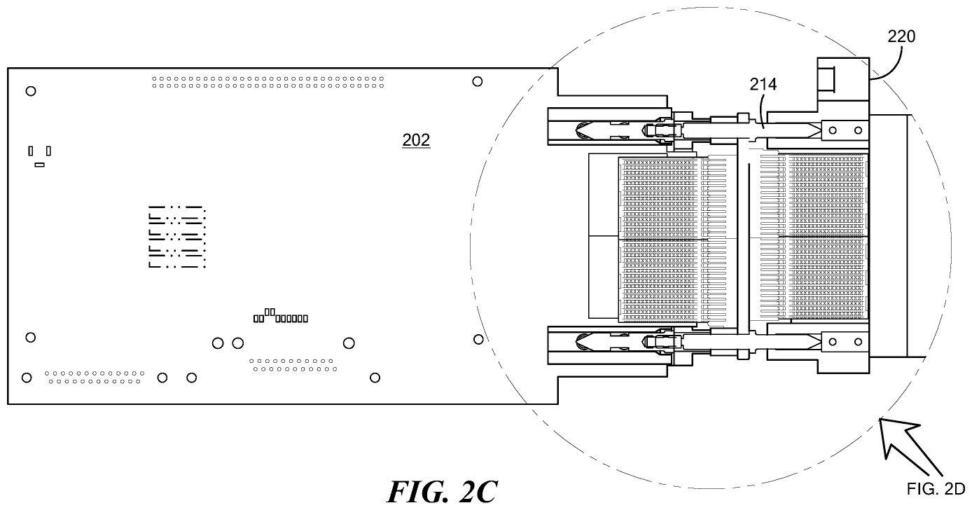

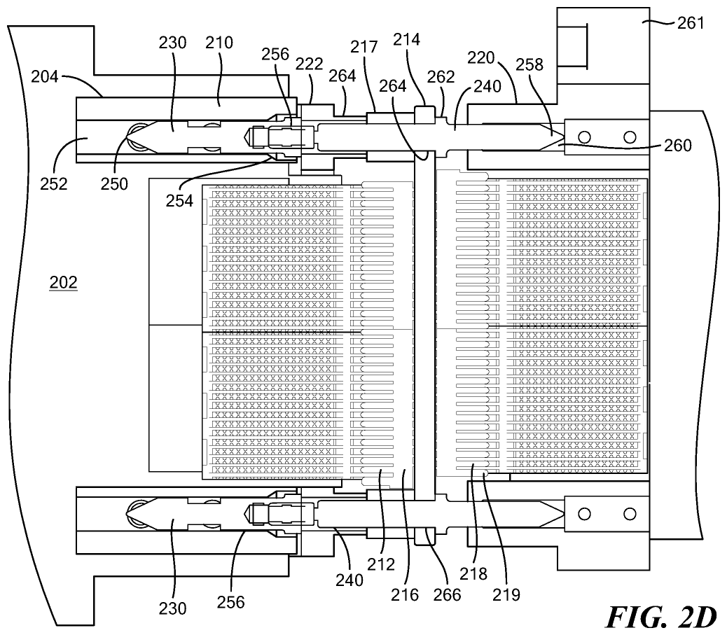

FIG. 2A shows an exploded side view, FIG. 2B shows a partially populated front view, FIG. 2C shows a side cross-sectional view, and FIG. 2D shows a portion of FIG. 2C in detail, of a system including one or more circuit boards 202 coupled to a backplane 204 by blind feedthrough connector assemblies 206 having coaxial alignment pins.

As best shown in FIG. 2A, a test circuit board 202 is secured to an alignment bracket 210, which may be similar to the alignment bracket 110 of FIG. 1, which may be generally U-shaped and features two alignment holes for the purpose of mating with the second alignment pin 230. A first connector 212 is coupled to the test circuit board to enable connection to other circuit boards, devices, etc. In the illustrated embodiment, an interposer board 214 includes a front connector 216 to connect to the first connector 212 of the test circuit board 202 and a back connector 218 to connect to a connector 219 of the UUT 220.

An alignment plate 222 is located between the interposer board 214 and the test circuit card 202. First alignment pins 240 and second alignment pins 230 align and/or mate the alignment interposer board 214 with the alignment plate 222 so that the interposer board 214 is fastened to and precisely positioned on the alignment plate 222. Test circuit board 202 and alignment bracket 210 are mated with the second alignment pins 230 so that the test connector 212 and the front connector 216 of the interposer board are precisely positioned with respect to each other. A spacer 217 may be used to achieve a desired spacing between the interposer board 214 and the alignment plate 222.

The first alignment pins 240 align and/or mate the alignment plate 222 and the UUT 220. This precisely positions the back connector 218 of the interposer board 214 and the UUT connector 219.

As best shown in FIG. 2D, a first end 250 of the second alignment pin 230 is inserted into a first alignment hole 252 in the alignment bracket 210, which is secured to the test board 202. A second end 254 of the second alignment pin 230 is mated to a first end 256 of the first alignment pin 240. In embodiments, a second end 258 of the first alignment pin 240 is inserted into a second alignment hole 260 in a bracket 261 of the UUT 220.

In the illustrated embodiment, the first alignment pin 240 includes a shoulder 262 to forcibly abut the UUT-side of the interposer board 214. The spacer 217 can abut the opposite side of the interposer board 214. The alignment plate 222 can include a standoff 264 to abut the spacer 217.

In embodiments, the second end 254 of the second alignment pin 230 is threadably mated to the first end 256 of the first alignment pin 240 so that the first and second alignment pins are coaxially aligned when completely mated together which aligns the first alignment hole 252 in the alignment bracket 210 and the second alignment hole 260 in the UUT 220. In embodiments, the second end 254 of the second alignment pin 230 may be flared to abut the alignment plate 222. The flared second end 254 may be larger than the width of the first alignment pin 240. As the first and second alignment pins 240, 230 are manipulated to complete engagement, the shoulder 262 of the first alignment pin is forced against the interposer board 214 and the flared second end 254 of the second alignment pin is forced against the alignment plate 222.

In embodiments, the interposer circuit board 214 has first and second mounting holes 264, 266 located in reference to the second alignment pin 240 locations. The mounting holes 264, 266 of the interposer circuit board 214 feature a diameter tolerance of +/−0.001 inches and serve as datums B and C for the interposer circuit board. The alignment plate 222 to which the interposer board 214 is mounted and toleranced to line up with the mounting holes 264, 266 on the interposer board. The first alignment pin 240 slides through the mounting holes 262, 264 on the interposer board 214 and through the hole and the slot on the alignment plate 222. In embodiments, the second alignment pin 230 is fastened to the first alignment pin 240 on the back side of the alignment plate with the use of hexagonal features, for example, on the first and second alignment pins 240, 230 for rotating one or both of the alignment pins. Once the first and second alignment pins 240, 230 are fully engaged, the interposer board 214 is fastened to the alignment plate 222 in a precise location. The first and second alignment pins 240, 230 may serve as fasteners, as well as precisely located guide pins for successfully mating connectors without damage.

It is understood that any practical number of first and/or alignment pins at any suitable locations can be used to meet the needs of a particular application. While a threaded configuration is shown in example embodiments, it is understood that any useful attached mechanism can be used to engage first and second alignment pin configurations. In addition, any practical mechanism can be used to manipulate first and second alignment pins to a desired configuration for positioning one or more connectors. Also, it is understood that any practical type of connector can be used.

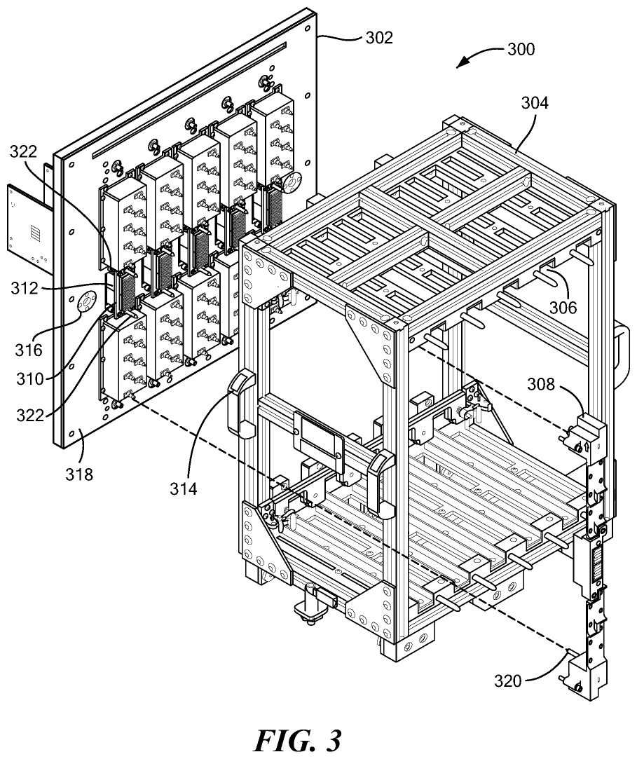

FIG. 3 shows an example system 300 including a backplane assembly 302 matable to a test basket 304 having respective slots 306 configured to receive UUT circuit cards 308 for connection to a back connector 310 of an interposer board 312, as described above, which is secured to the backplane assembly. In embodiments, basket datum pins 314 mate with datum holes/bushings 316 on an alignment plate 318 of the backplane assembly 302.

In the illustrated embodiment, the UUT 308 is aligned to the test basket 304 by alignment pins 320 that serve as a datum on the UUT. In embodiments, the positions of mounting holes for various blind mate connections, such as coolant, RF, connector, etc., on the UUT 308 are established from respective datum pins.

As described above in detail, alignment pins 322 extending through the respective interposer boards 312 may be precisely located in relation to the one or more datum, such as the datum bushings 316 on the alignment plate 318.

As used herein, the term “interposer board” should be construed broadly to include any type of circuit card having at least first and second connectors and any type of circuitry to provide electrical connections between the at least first and second connectors.

Various embodiments of the concepts systems and techniques are described herein with reference to the related drawings. Alternative embodiments can be devised without departing from the scope of the described concepts. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to element or structure “A” over element or structure “B” include situations in which one or more intermediate elements or structures (e.g., element “C”) is between element “A” and element “B” regardless of whether the characteristics and functionalities of element “A” and element “B” are substantially changed by the intermediate element(s).

The following definitions and abbreviations are to be used for the interpretation of the claims and the specification.

As used herein, the terms “comprises,” “comprising,” “includes,” “including,” “has,” “having,” “contains” or “containing,” or any other variation thereof, are intended to cover a non-exclusive inclusion. For example, a method, article, or apparatus that comprises a list of elements is not necessarily limited to only those elements but can include other elements not expressly listed or inherent to such method, article, or apparatus.

Additionally, the term “exemplary” is used herein to mean “serving as an example, instance, or illustration.” Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, e.g., two, three, four, five, etc. The term “connection” can include an indirect “connection” and a direct “connection”.

References in the specification to “one embodiment,” “an embodiment,” “an example embodiment,” or variants of such phrases indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection knowledge of one skilled in the art to affect such feature, structure, or characteristic in connection with other embodiments whether or not explicitly described.

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” surface can become a “lower” surface simply by turning the object over. Nevertheless, it is still the same surface and the object remains the same. Also, as used herein, “and/or” means “and” or “or”, as well as “and” and “or.” Moreover, all patent and non-patent literature cited herein is hereby incorporated by references in their entirety.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements.

Having described exemplary embodiments, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. An assembly, comprising:
a circuit card having a first connector;
an alignment bracket coupled to the circuit card, the alignment bracket having a bracket mounting hole;
an interposer board having a front connector and a back connector and an interposer mounting hole, wherein the front connector is mated with the first connector and the back connector is configured and positioned to mate with a test connector of a unit under test (UUT);
an alignment plate having a plate mounting hole;
a first alignment pin having first and second ends, wherein the first end is captured by the interposer mounting hole and the plate mounting hole, and the second end is configured for insertion into a bracket of a Unit Under Test (UUT); and
a second alignment pin having first and second ends, wherein the first end is captured in the bracket mounting hole of a test circuit card and the second end is secured to the first end of the first alignment pin.

2. The system according to claim 1, wherein the second end of the second alignment pin is threadably engaged to the first end of the first alignment pin.

3. The system according to claim 1, wherein the second end of the second alignment pin is secured to the first end of the first alignment pin with a threaded male/female connection.

4. The system according to claim 1, wherein the first and second alignment pins are concentrically positioned.

5. The system according to claim 1, wherein the first alignment pin includes a shoulder to abut a surface of the interposer board.

6. The system according to claim 1, wherein the interposer plate is positioned in relation to the alignment plate to position the back connector for mating with the test connector of the UUT.

7. The system according to claim 1, wherein the back connector comprises a multigig connector.

8. The system according to claim 1, wherein the second end of the second alignment pin is flared to abut a surface of the alignment plate.

9. The system according to claim 1, wherein the alignment plate forms part of a backplane assembly.

10. The system according to claim 1, further comprising a test basket coupled to the alignment plate.

11. The system according to claim 10, wherein the test bracket includes slots to accept the UUT.

12. A method, comprising:
employing a circuit card having a first connector;
employing an alignment bracket coupled to the circuit card, the alignment bracket having a bracket mounting hole;
employing an interposer board having a front connector and a back connector and an interposer mounting hole, wherein the front connector is mated with the first connector and the back connector is configured and positioned to mate with a test connector of a unit under test (UUT);
employing an alignment plate having a plate mounting hole;
employing a first alignment pin having first and second ends, wherein the first end is captured by the interposer mounting hole and the plate mounting hole, and the second end is configured for insertion into a bracket of a Unit Under Test (UUT); and
employing a second alignment pin having first and second ends, wherein the first end is captured in the bracket mounting hole of a test circuit card and the second end is secured to the first end of the first alignment pin.

13. The method according to claim 12, wherein the second end of the second alignment pin is threadably engaged to the first end of the first alignment pin.

14. The method according to claim 12, wherein the second end of the second alignment pin is secured to the first end of the first alignment pin with a threaded male/female connection.

15. The method according to claim 12, wherein the first and second alignment pins are concentrically positioned.

16. The method according to claim 12, wherein the first alignment pin includes a shoulder to abut a surface of the interposer board.

17. The method according to claim 12, wherein the interposer plate is positioned in relation to the alignment plate to position the back connector for mating with the test connector of the UUT.

18. The method according to claim 12, wherein the back connector comprises a multigig connector.

19. The method according to claim 12, wherein the second end of the second alignment pin is flared to abut a surface of the alignment plate.

20. The method according to claim 12, further comprising a test basket coupled to the alignment plate.
